(19) United States
(12) Patent Application Publication
(10) Pub. No.: US 2017/0159169 A1
(43) Pub. Date: Jun. 8, 2017

(54) PROCESS FOR MANUFACTURING NICKEL OXIDE FILMS WITH HIGH CONDUCTIVITY

(71) Applicant: Ming Chi University of Technology, New Taipei City (TW)

(72) Inventors: Sheng-Chi CHEN, New Taipei City (TW); Tsung-Yen KUO, New Taipei City (TW); Hsin-Chih LIN, New Taipei City (TW)

(21) Appl. No.: 14/956,853

(22) Filed: Dec. 2, 2015

(51) Int. Cl. C23C 14/34; C23C 14/08; H01J 37/34; C23C 14/35

(52) U.S. Cl. CPC C23C 14/3414; C23C 14/35; C23C 14/3485; C23C 14/3457; C23C 14/085; H01J 37/3467; H01J 37/3405; H01J 37/3426

(57) ABSTRACT

The invention provides a process for manufacturing nickel oxide films with high conductivity, comprising steps of: operating a high power impulse magnetron sputtering system, HIPIMS system, in an argon and oxygen mixture, at peak power density higher than 1000 W/cm² under a low duty cycle; and sputtering a Ni target to form the p-type NiO film with high conductivity on a substrate, the duty cycle=tₒₙ/(tₒₙ+t_{off}), wherein tₒₙ is time of pulse on and t_{off} is time of pulse off.

### BACKGROUND OF THE INVENTION

Field of the Invention

The present invention relates to a process for manufacturing transparent conductive oxide films, more particularly to a process for manufacturing nickel oxide films.

Description of the Prior Art

Most of transparent conductive oxide (TCO) films semiconductor material.

They may be divided into two types, one type of p-type TCO and another type of n-type TCO. The n-type TCO process was developed earlier and is an established technology. Nowadays, indium tin oxide (ITO) has been commercial products in the industry that belongs to the n-type TCO. However, in the application of opto-electronic components such as diodes and transistors, developing a highly conductive p-type TCO films is an important research topic. In some researches, it has been found NiO, CuAlO₂, ZnO:N, Cu₂O and SrCu₂O₂ have potential as a p-type TCO, wherein NiO film has a wide band gap range (3.6-4.0 eV), high dielectric constant (S˜11.9), antiferromagnetic properties and can be made into p-type film with good conductivity, and so on. Due to these special optical, electrical and magnetic properties of NiO, there are opportunities for NiO to be used in solar cells, p-type film transistors, giant magnetoresistance (GMR) sensors and electrochromic and aluminum gallium nitride/gallium nitride heterostructure field effect transistor of the insulating layer, and so on.

With 1:1 stoichiometric ratio of Ni:O of atomic numbers, NiO has resistivity up to 10¹³ Ω-cm, being an insulator. The resistivity of NiO films can be reduced by adjusting process parameters to produce large amounts of Ni³⁺ ions in the film. Whenever two sites of Ni²⁺ ions are replaced by two Ni³⁺ ions, a vacancy of Ni²⁺ ion site is formed, thus hole concentration and p-type conductivity of nickel oxide film can be increased.

There are many kinds of process for manufacturing NiO films such as spray pyrolysis, plasma enhanced chemical vapor deposition, evaporation deposition and magnetron sputtering methods. It has been found the magnetron sputtering drives to achieve nickel oxide films with better transmittance and conductivity, and the magnetron sputtering process has good characteristics such as high deposition rate, suitable to large area deposition and excellent uniformity, thus the magnetron sputtering is bound to become the industry production preferred. However, the traditional magnetron sputtering process has a low sputtering power that may cause low ionization (that is, less Ni³⁺ ions), and therefore it would be difficult to develop NiO films with high conductivity.

It is desirable to provide a process for manufacturing nickel oxide films with high conductivity to overcome above-mentioned drawbacks.

### SUMMARY OF THE INVENTION

It is an object of the present invention to disclose a process for manufacturing nickel oxide films with high conductivity. The process comprises operating a high power impulse magnetron sputtering system, HIPIMS system, under a low duty cycle; and sputtering a Ni target to form the p-type NiO film with high conductivity on a substrate, the duty cycle=tₒₙ/(tₒₙ+t_{off}), wherein tₒₙ is time of pulse on and t_{off} is time of pulse off. The traditional direct current magnetron sputtering (DCMS) system has a low sputtering power that may cause atoms ionization lower than 5%. The present invention discloses a HIPIMS system having feature of producing high density plasma that may cause ionization of sputtering atoms up to 70% in the film. Therefore, the amount of Ni³⁺ ions in the film can be increased highly so that the conductivity of p-type NiO film can be enhanced greatly.

Accordingly, the present invention provides a process for manufacturing nickel oxide films with high conductivity. The process comprises operating a high power impulse magnetron sputtering system, HIPIMS system, in an argon and oxygen mixture, at peak pulse power density higher than 1000 W/cm², under a duty cycle lower than 3.2%; and sputtering a Ni target to form the p-type NiO film with high conductivity on a substrate, the duty cycle=tₒₙ/(tₒₙ+t_{off}), wherein tₒₙ is time of pulse on and t_{off} is time of pulse off.

### BRIEF DESCRIPTION OF DRAWING

The features of the invention believed to be novel are set forth with particularity in the appended claims. The invention itself, however, may be best understood by reference to the following detailed description of the invention, which describes an exemplary embodiment of the invention, taken in conjunction with the accompanying drawings, in which:

FIG. 1 shows a schematic view of layer structure including nickel oxide film with high conductivity of a preferred embodiment according to the present invention.

FIGS. 2a-2g show oscilloscope graphs displaying peak pulse voltage and peak pulse current of the target, wherein FIG. 2a has time of pulse tₒₙ:t_{off}=50:0 μs; FIG. 2b has time of pulse tₒₙ:t_{off}=50:500 μs; FIG. 2c has time of pulse tₒₙ:t_{off}=50:1000 μs; FIG. 2d has time of pulse tₒₙ:t_{off}=50:1500 μs; FIG. 2e has time of pulse tₒₙ:t_{off}=50:2000 μs; FIG. 2f has time of pulse tₒₙ:t_{off}=50:2500 μs; and FIG. 2g has time of pulse tₒₙ:t_{off}=50:3000 μs.

FIG. 3a shows peak pulse current and average current of the target; and FIG. 3b shows the change of peak pulse power density of the target with duty cycle of HIPIMS, in which partial pressure of oxygen is fixed at 50%.

FIG. 4 shows spectrum of optical emission spectroscopy (OES) of real time detecting NiO film, in which (a) is NiO film formed by DCMS (Duty cycle=100%); and (b) is NiO film formed by HIPIMS (Duty cycle=1.6%), partial pressure of oxygen is fixed at 50%.

FIG. 5 shows the change of deposition rate of NiO film with duty cycle of HIPIMS, in which partial pressure of oxygen is fixed at 50%.

FIG. 6 shows XRD pattern of sputtering NiO film in different duty cycles, in which partial pressure of oxygen is fixed at 50%.

FIG. 7 shows the change of grain size of NiO film with duty cycle, in which partial pressure of oxygen is fixed at 50%.

FIG. 8 shows the change of the resistivity of NiO film with duty cycle, in which partial pressure of oxygen is fixed at 50%.

FIG. 9 shows the change of the carrier concentration and carrier mobility of NiO film with duty cycle, in which partial pressure of oxygen is fixed at 50%.

FIG. 10a shows spectrum of X-ray photoelectron spectroscopy of Ni region of NiO film with duty cycle of 100%, in which partial pressure of oxygen is fixed at 50%; and

FIG. 10b shows spectrum of X-ray photoelectron spectroscopy of Ni region of NiO film with duty cycle of 1.6%, in which partial pressure of oxygen is fixed at 50%.

FIGS. 11a-11d show FE-SEM images of sputtering NiO film in different duty cycles, partial pressure of oxygen is fixed at 50%, wherein FIG. 11a has 100% of duty cycle; FIG. 11b has 3.2% of duty cycle; FIG. 11c has 2.4% of duty cycle; and FIG. 11d has 1.6% of duty cycle.

FIGS. 12a-12b show AFM surface images of sputtering NiO film in different duty cycles, partial pressure of oxygen is fixed at 50%, wherein FIG. 12a has 100% of duty cycle; and FIG. 12b has 1.6% of duty cycle.

FIGS. 13a-13c show TEM cross-sectional images of DCMS (duty cycle=100%) sputtering NiO film in different amplification factors, partial pressure of oxygen is fixed at 50%, wherein FIG. 13a has 100 K of amplification factor; FIG. 13b is crystal lattice image of region I of FIG. 13a in 800 K of amplification factor; and FIG. 13c is crystal lattice image of region II of FIG. 13a in 800 K of amplification factor.

FIGS. 14a-14c show TEM cross-sectional images of HIPIMS (duty cycle=1.6%) sputtering NiO film in different amplification factors, partial pressure of oxygen is fixed at 50%, wherein FIG. 14a has 100 K of amplification factor; FIG. 14b is crystal lattice image of region I of FIG. 14a in 800 K of amplification factor; and FIG. 14c is crystal lattice image of region II of FIG. 14a in 800 K of amplification factor.

FIG. 15 shows the change of transmittance of NiO film with incident light wavelength in different duty cycles.

### DETAILED DESCRIPTION OF THE INVENTION

The present invention provides a process for manufacturing nickel oxide films with high conductivity. A layer structure obtained by the process comprises a substrate and a nickel oxide film formed on the substrate. The process comprises operating a high power impulse magnetron sputtering system, HIPIMS system, in an argon and oxygen mixture, at peak pulse power density higher than 1000 W/cm², under a duty cycle lower than 3.2%; and sputtering a Ni target to form the p-type NiO film with high conductivity on a substrate, the duty cycle=tₒₙ/(tₒₙ+t_{off}), wherein tₒₙ is time of pulse on and t_{off} is time of pulse off.

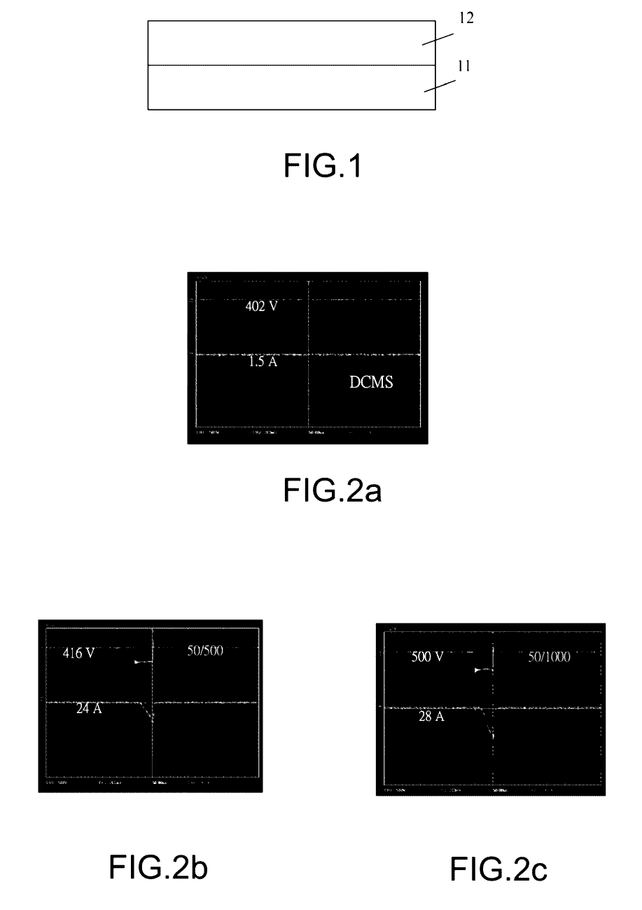

FIG. 1 shows a schematic view of a layer structure including nickel oxide film with high conductivity of a preferred embodiment according to the present invention.

According to FIG. 1, a layer structure obtained by the process comprises a substrate 11 and a nickel oxide film 12 formed on the substrate 11. The substrate 11 is made by glass or silica. The nickel oxide film 12 is formed on the substrate 11 by HIPIMS, wherein the nickel oxide film 12 has a thickness of 100 nm.

According to FIG. 1, in a preferred embodiment of the present invention, a layer structure including nickel oxide film with high conductivity includes a substrate 11 and a nickel oxide film 12, wherein the nickel oxide film 12 has grain size in a range of 5 nm-6.5 nm; resistivity in a range of 0.19˜0.07 Ω-cm; and carrier concentration in a range of 2.70×10¹⁹ cm⁻³˜2.86×10²¹ cm⁻³. The nickel oxide film 12 is p-type conductivity.

In an embodiment, the thickness of nickel oxide film 12 is measured by profilometer and atomic force microscopy (DI-Dimension 3100). Phase structure of the nickel oxide film 12 is measured by Cu—Kα of X-ray diffraction (Philips PANalytical-X'Pert PRO MRD). Resistivity, carrier concentration and carrier mobility of the NiO film are measured by Hall effect measurement (Advance Design Technology AHM-800B). Transmittance of the NiO film is measured by Ultraviolet-visible spectroscopy (JASCO-V750). Surface morphology is analyzed by Field-Emission Scanning Electron Microscope (JEOL JEM-6701) and atomic force microscopy (DI-Dimension 3100). Chemical analysis of the NiO film composition is measured by Electron Probe X-Ray Microanalyzer (JEOL JXA-8200) and X-ray photoelectron spectroscopy (VG Scientific ESCALAB 250).

### Embodiments

NiO film with a thickness of 100 nm is formed on a substrate, for example glass and Si substrate with a reactive magnetron sputtering process by high power impulse magnetron sputtering system, HIPIMS system sputtering Ni target. The power source of HIPIMS is a pulse generator fed with a DC power source. In the embodiment, NiO film is deposited with different duty cycles.

### Comparative Examples

NiO film with a thickness of 100 nm is formed on a substrate, for example glass and Si substrate with a reactive magnetron sputtering process by direct current magnetron sputtering system, DCMS system sputtering Ni target. DCMS is always powering on so that the duty cycle=tₒₙ/(tₒₙ+t_{off})=100%, wherein tₒₙ is time of pulse on and t_{off} is time of pulse off.

In an embodiment, NiO film with a thickness of 100 nm is formed on a substrate, for example glass and Si substrate with a reactive magnetron sputtering process by high power impulse magnetron sputtering system, HIPIMS system sputtering Ni target. The power source of HIPIMS is a pulse generator (SPIK2000H, Shen Chang Electric Co., LTD) fed with a DC power source. In the embodiment, NiO film is deposited with different duty cycles by changing t_{off} with fixing tₒₙ, detailed process parameters as listed in Table 1.

TABLE 1
Process parameters setting of NiO film

| Sputtering | |
|---|---|
| parameter | Parameters setting |
| Substrate | glass and Si substrate |
| material | |
| Argon and | 8:8 SCCM |
| oxygen flow ratio | |
| Working | 5 mTorr |
| pressure | |
| Background | <5 × 10⁻⁷ Torr |
| vacuum | |
| DC output | 0.3 kW |
| power | |
| tₒₙ:t_{off} | 50:500, 50:1000, 50:1500, 50:2000, 50:2500 |
| | and 50:3000 |
| Substrate | Ambient temperature |
| temperature | |

1. The Influence of tₒₙ and t_{off} to Peak Pulse Power and Peak Pulse Current of the Target

The relationship of time of pulse (tₒₙ/t_{off}) and duty cycle is shown as listed in Table 2. In the embodiment, tₒₙ is fixed on 50 μs, and t_{off} is changed in a range from 500 μs to 3000 μs. As t_{off} is 500 s, duty cycle is 9.1%. With increasing t_{off} to 1000 μs, 1500 μs, 2000 μs, 2500 μs and 3000 μs, the duty cycle can be reduced largely to 4.8%, 3.2%, 2.4%, 2.0% and 1.6%.

TABLE 2
The relationship of time of pulse (tₒₙ/t_{off}) and duty cycle

| tₒₙ/t_{off} time (μs) | Duty cycle (%) |
|---|---|
| 50/500 | 9.1 |
| 50/1000 | 4.8 |
| 50/1500 | 3.2 |
| 50/2000 | 2.4 |
| 50/2500 | 2.0 |
| 50/3000 | 1.6 |

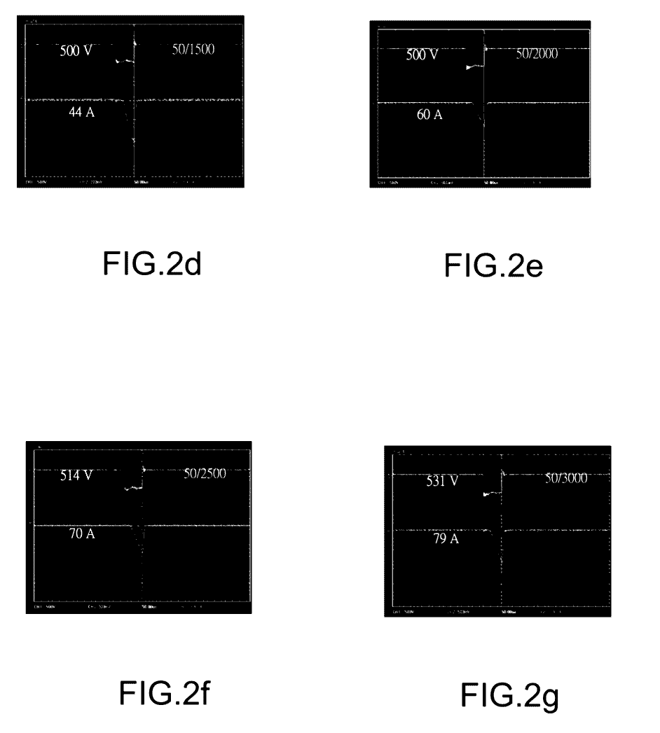

FIGS. 2a-2g show oscilloscope graphs displaying peak pulse voltage and peak pulse current of the target, wherein FIG. 2a has time of pulse tₒₙ:t_{off}=50:0 μs; FIG. 2b has time of pulse tₒₙ:t_{off}=50:500 μs; FIG. 2c has time of pulse tₒₙ:t_{off}=50:1000 μs; FIG. 2d has time of pulse tₒₙ:t_{off}=50:1500 μs; FIG. 2e has time of pulse tₒₙ:t_{off}=50:2000 μs; FIG. 2f has time of pulse tₒₙ:t_{off}=50:2500 μs; and FIG. 2g has time of pulse tₒₙ:t_{off}=50:3000 μs. In an example of DCMS, t_{off} is 0 μs, and thus duty cycle is 100%, peak pulse current of the target is only 1.5 A in this case, as shown in FIG. 2a. In an embodiment of HIPIMS, as t_{off} is 500 μs and tₒₙ is fixed on 50 μs, duty cycle is 9.1%. With increasing t_{off} to 1000 μs, 1500 μs, 2000 μs, 2500 μs and 3000 μs with tₒₙ is fixed on 50 μs, the duty cycle can be reduced largely to 4.8%, 3.2%, 2.4%, 2.0% and 1.6%. As tₒₙ is fixed, the duty cycle can be reduced by increasing t_{off}. More the energy stored in the capacitor, pulse released in an instant larger peak pulse current of the target. Thus, as the duty cycle is reduced to 1.6%, instant peak pulse current of the target can reach about 79 A of maximum, as shown in FIG. 2g.

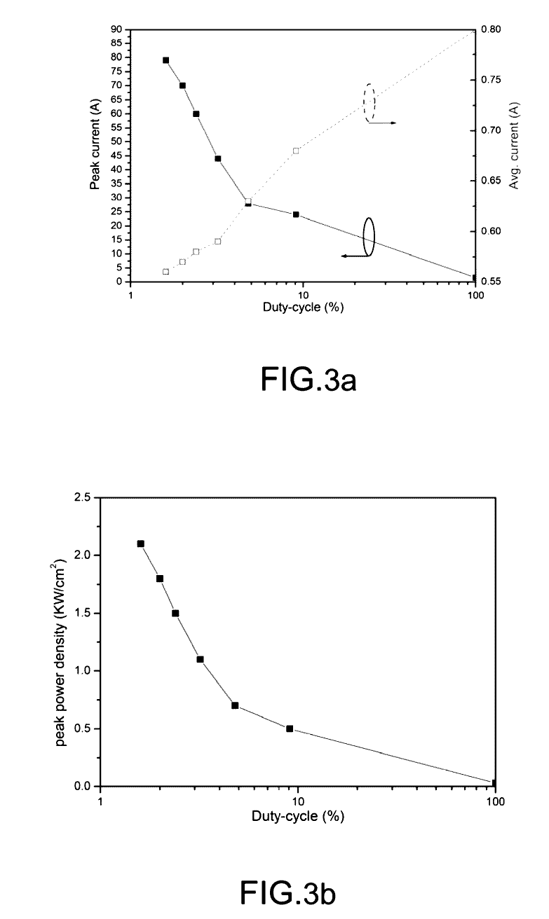

FIG. 3a shows peak pulse current and average current of the target. As can be seen from FIG. 3a, the instant peak pulse current of the target is increased with the duty cycle is reducing, and the instant peak pulse current of the target can reach about 79 A of maximum. On the other hand, average current of the target is reduced with the duty cycle is reducing because the average current of the target is obtained with peak pulse current of the target divided by total time of tₒₙ and t_{off}. Thus, the lower duty cycle, the less the average current of the target. FIG. 3b shows the change of peak pulse power density of the target with duty cycle of HIPIMS, in which partial pressure of oxygen is fixed at 50%. As can be seen from FIG. 3b, the peak pulse power density of the target is increased rapidly with the duty cycle is reducing. As the duty cycle is 9.1%, the peak pulse power density of the target is 0.5 KW/cm². With reducing the duty cycle to 4.8%, 3.2%, 2.4% and 2.0%, the peak pulse power density of the target may be increased to 0.7 KW/cm², 1.1 KW/cm², 1.5 KW/cm² and 1.8 KW/cm². Further, as the duty cycle is reduced to 1.6%, the peak pulse power density of the target can reach about 2.1 KW/cm² of maximum. It will be known from the above values as the duty cycle reduced below 3.2%, the peak pulse power density of the target is higher than 1 KW/cm² that may meet the requirement of the embodiment.

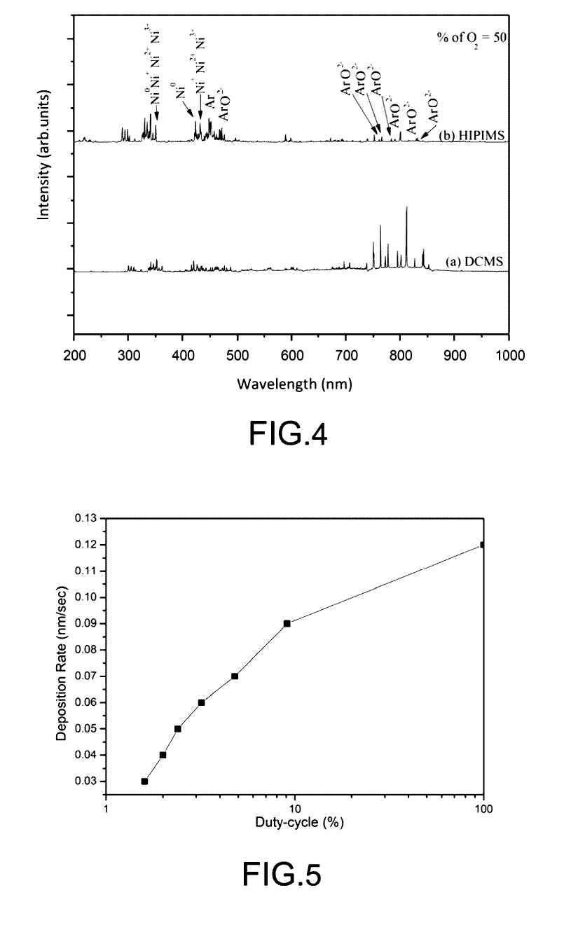

FIG. 4 shows spectrum of optical emission spectroscopy (OES) of real time detecting NiO film, in which (a) is NiO film deposited by DCMS (Duty cycle=100%); and (b) is NiO film deposited by HIPIMS (Duty cycle=1.6%), partial pressure of oxygen is fixed at 50%. Identified by Ar and O peaks as shown in FIG. 4 most appear between 750 nm and 800 nm, and Ni ions peaks mainly appear in a range between 250 nm and 500 nm. It can be seen from FIG. 4, in an example of DCMS with duty cycle of 100%, the peaks at long wavelength (low energy) region from 750 nm to 800 nm have higher intensity. On the other hand, in an embodiment of HIPIMS with duty cycle of 1.6%, the peaks at short wavelength (high energy) region from 200 nm to 500 nm have higher intensity obviously. The intensity of Ni ions peaks is increased largely in HIPIMS process that may describe HIPIMS can enhance the energy and ionization of sputtering Ni atoms.

2. Deposition Rate of NiO Film

FIG. 5 shows the change of deposition rate of NiO film with duty cycle of HIPIMS, in which partial pressure of oxygen is fixed at 50%. As can be seen from FIG. 5, as the duty cycle of sputtering is reduced, the sputtering rate of NiO film is reduced rapidly. In an example of DCMS with duty cycle of 100%, the highest sputtering rate about 0.12 nm/sec is obtained. On the other hand, in an embodiment of HIPIMS with duty cycle of 9.1%, the deposition rate of NiO film deposition rate is reduced to 0.09 nm/sec. As the duty cycle is reduced to 4.8%, the deposition rate of NiO film deposition rate is reduced to 0.07 nm/sec. Further, as the duty cycle is reduced to 3.2%, 2.4%, 2% and 1.6%, the deposition rate of NiO film is reduced to 0.06 nm/sec, 0.05 nm/sec, 0.04 nm/sec and 0.03 nm/sec, respectively.

3. Analysis of the Phase Structure

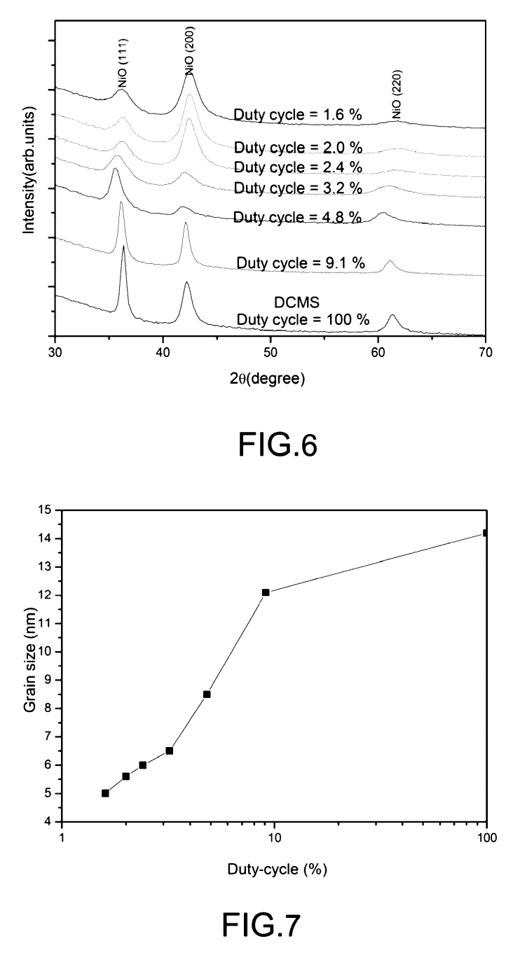

FIG. 6 shows XRD pattern of sputtering NiO film in different duty cycles, in which partial pressure of oxygen is fixed at 50%. There are three peaks appearing at diffraction angle 2θ of 36°, 42° and 61° in FIG. 6, identified by JCPD card, they are NiO(111), NiO(200) and NiO(220) respectively. It can be found from FIG. 6 in DCMS with duty cycle of 100% and HIPIMS with duty cycle higher than 3.2%, the peak of (111) plane has intensity larger than (200) plane thereof, however as HIPIMS with duty cycle lower than 2.4%, the peak of (200) plane has intensity larger than (111) plane thereof. Because (200) plane of NiO film has the lowest surface energy, the sputtering rate is low and peak pulse power density is high so that deposited atoms have enough time and energy to move to balance sites for reducing entire energy of the film as the duty cycle is lower than 2.4%. Therefore, the NiO film may have deposition toward (200) plane.

Next, FIG. 7 shows the change of grain size of NiO film with duty cycle according Scherrer formula, calculated by diffraction peaks at (200) plane, in which partial pressure of oxygen is fixed at 50%. The grain size of NiO film by using DCMS is about 14.2 nm. The grain size of NiO film by using HIPIMS with duty cycle of 9.1% is reduced to 12.1 nm. Further, as the duty cycle is reduced to 4.8%, 3.2%, 2.4%, 2.0% and 1.6%, the grain size of NiO film is reduced to 8.5 nm, 6.5 nm, 6.0 nm, 5.6 nm and 5 nm respectively. The result may describe that the grain size of NiO film can be reduced by using HIPIMS with reducing the duty cycle.

4. Analysis of electric properties of NiO film

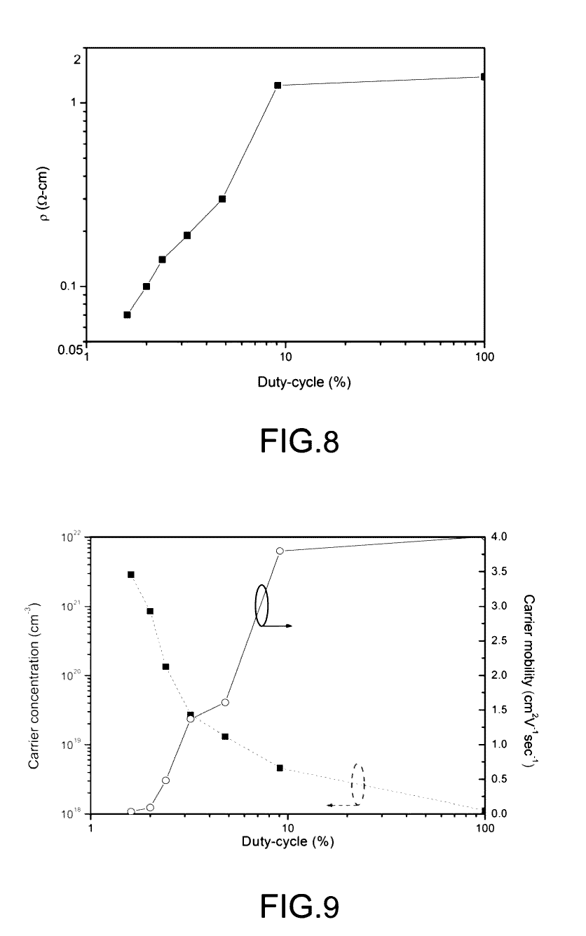

FIG. 8 shows the change of the resistivity of NiO film with duty cycle, in which partial pressure of oxygen is fixed at 50%. As can be seen from FIG. 8, the resistivity of NiO film is reduced with the duty cycle reducing. The resistivity of NiO film is 1.39 Ω-cm by using DCMS to deposit NiO film. The resistivity of NiO film is 1.25 Ω-cm by using HIPIMS with the duty cycle of 9.1% to deposit NiO film. The resistivity of NiO film is reduced to 0.3 Ω-cm rapidly as using HIPIMS with the duty cycle of 4.8% to deposit NiO film. Further, as the duty cycle is reduced to 3.2%, 2.4%, 2.0% and 1.6%, the resistivity of NiO film is reduced to 0.19 Ω-cm, 0.14 Ω-cm, 0.1 Ω-cm and 0.07 Ω-cm respectively.

FIG. 9 shows the change of the carrier concentration and carrier mobility of NiO film with duty cycle, in which partial pressure of oxygen is fixed at 50%. As can be seen from FIG. 9, the carrier concentration of NiO film is increased with the duty cycle reducing. The carrier concentration of NiO film is at low level about 1.1×10¹⁸ cm⁻³ by using DCMS to deposit NiO film. The carrier concentration of NiO film is increased to 1.42×10¹⁸ cm⁻³ by using HIPIMS with the duty cycle of 9.1% to deposit NiO film. The carrier concentration of NiO film is further increased to 1.31×10¹⁹ cm⁻³ as using HIPIMS with the duty cycle of 4.8% to deposit NiO film. Further, as the duty cycle is reduced to 3.2%, 2.4%, 2.0% and 1.6%, the carrier concentration of NiO film is increased to 2.70×10¹⁹ cm⁻³, 1.34×10²⁰ cm⁻³, 8.49×10²⁰ cm⁻³ and 2.86×10²¹ cm⁻³.

It can be found that all the carriers are positive values, the result describing that all the NiO films are of p-type conductivity in different duty cycles. Because HIPIMS has property of largely enhancing ionization of sputtering atoms and peak pulse power density of the target is increased largely with the duty cycle reducing (referring to FIG. 3b), the NiO film has an increased ionization of sputtering atoms at a lower duty cycle, and the amount of Ni³⁺ ions in the film can be increased highly. Whenever two sites of Ni²⁺ ions are replaced by two Ni³⁺ ions, a vacancy of Ni²⁺ ion site is formed, thus the amount of holes can be increased with reducing the duty cycle, and the carrier (hole) concentration also can be increased. In contrast, carrier mobility decreases with reducing the duty cycle. The grain size of NiO film decreases with reducing the duty cycle (see FIG. 7), and refined grains may obtain more grain boundaries. In addition, the amount of vacancy sites also increases with reducing the duty cycle. The grain boundaries and vacancy sites in the film would hinder the movement of carriers so that the carrier mobility of NiO film may decrease with reducing the duty cycle.

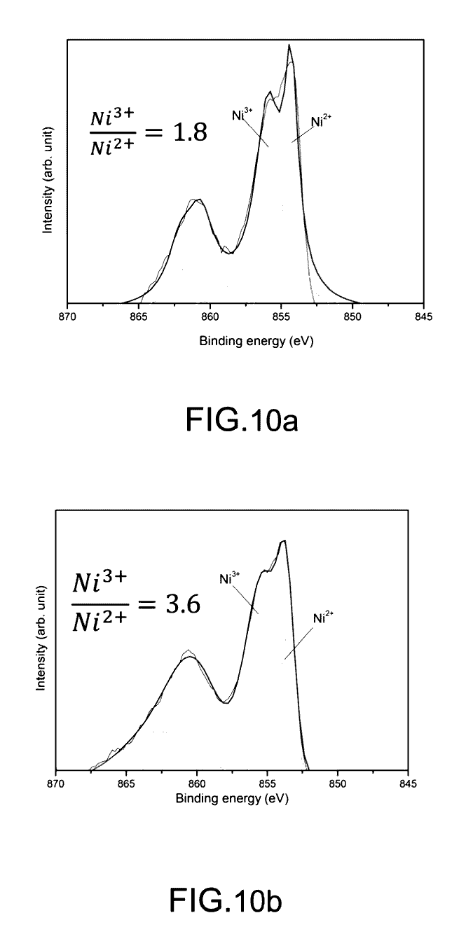

X-ray photoelectron spectroscopy is used to analyze chemical bonding state of NiO film with curve fitting of Ni2p^{3/2} spectrum of sputtering NiO film by the duty cycle of 100% and 1.6%, result obtained as shown in FIG. 10a and FIG. 10b. The result of the curve fitting of Ni2p^{3/2} spectrum of NiO film shows two peaks of 856.0 eV and 854.4 eV as the duty cycle is 100%; and two peaks of 855.8 eV and 853.8 eV as the duty cycle is 1.6%. According to the literature, electron binding energy of Ni2p^{3/2} in NiO in a range between about 853.8 eV to 854.4 eV, and electron binding energy of Ni2p^{3/2} in Ni₂O₃ in a range between about 855.8 eV to 857.3 eV. It can be seen from XPS spectra of FIGS. 10a and 10b, both Ni²⁺ and Ni³⁺ ions exist in NiO film. Integral intensity of Ni³⁺ peak is slightly larger than that of Ni²⁺ peak, and curve area ratio of Ni³⁺/Ni²⁺ is 1.8 as the sputtering duty cycle is 100%. However, Ni³⁺ peak is enlarged and Ni²⁺ peak gets smaller, and curve area ratio of Ni³⁺/Ni²⁺ is increased largely to 3.6 as the duty cycle is reduced to 1.6%. Because the peak pulse power density of the target is increased, ionization of sputtering atoms can be enhanced.

5. Analysis of Microstructure

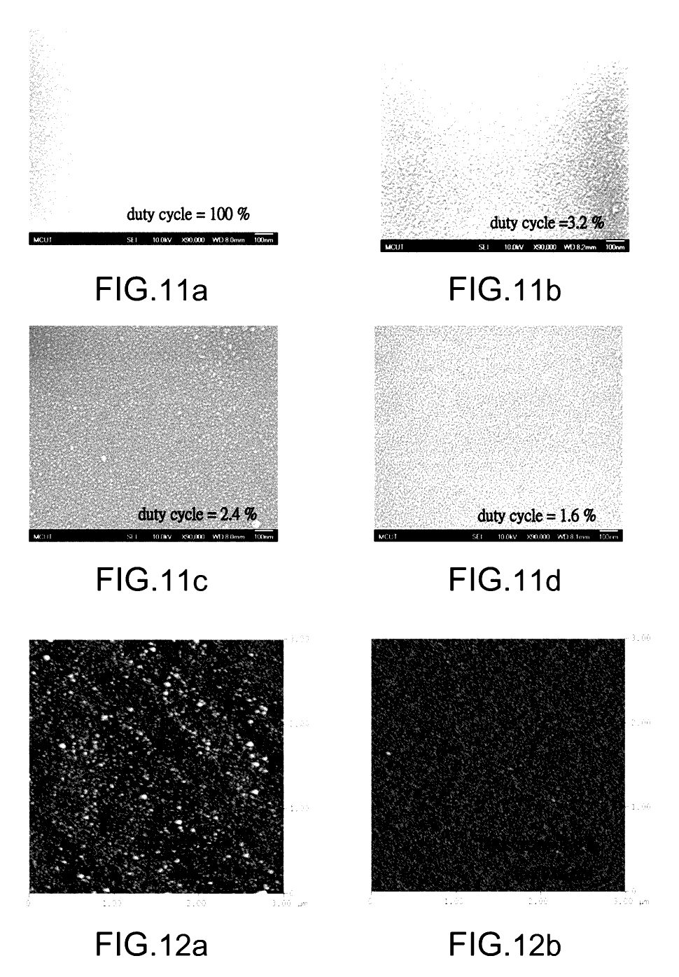

FIGS. 12a-12b show FE-SEM images of sputtering NiO film in different duty cycles, partial pressure of oxygen is fixed at 50%, wherein FIG. 11a has 100% of duty cycle; FIG. 11b has 3.2% of duty cycle; FIG. 11c has 2.4% of duty cycle; and FIG. 11d has 1.6% of duty cycle. As can be seen from FIG. 11a, particles on the surface of NiO film are coarse as the duty cycle is 100% (DCMS). The particles on the surface of NiO film are getting fine with reducing the duty cycle, as shown in FIGS. 11b to 11d. The result is consistent with the change of grain size of NiO film of FIG. 7. Apparently, the microstructure on the surface of sputtering NiO film can be fined by using HIPIMS with reducing the duty cycle.

FIGS. 12a-12b show AFM surface images of sputtering NiO film in different duty cycles, wherein FIG. 12a has 100% of duty cycle; and FIG. 12b has 1.6% of duty cycle. As can be seen from FIG. 12a, the surface of NiO film is coarse, and surface roughness of the NiO film about 1.11 nm as the duty cycle is 100%. In FIG. 12b, the surface of NiO film has become flat, and surface roughness of NiO film is apparently reduced to about 0.66 nm as the duty cycle is reduced to 1.6%. The change of AFM surfacephase images of sputtering NiO film in FIGS. 12a-12b is consistent with the change FE-SEM images of sputtering NiO film in FIGS. 11a-11d. The above phenomenon can also be attributed to HIPIMS being considered a high-energy ion bombardment, with sputtering atoms having higher energies, therefore more compact and smoother films can be formed.

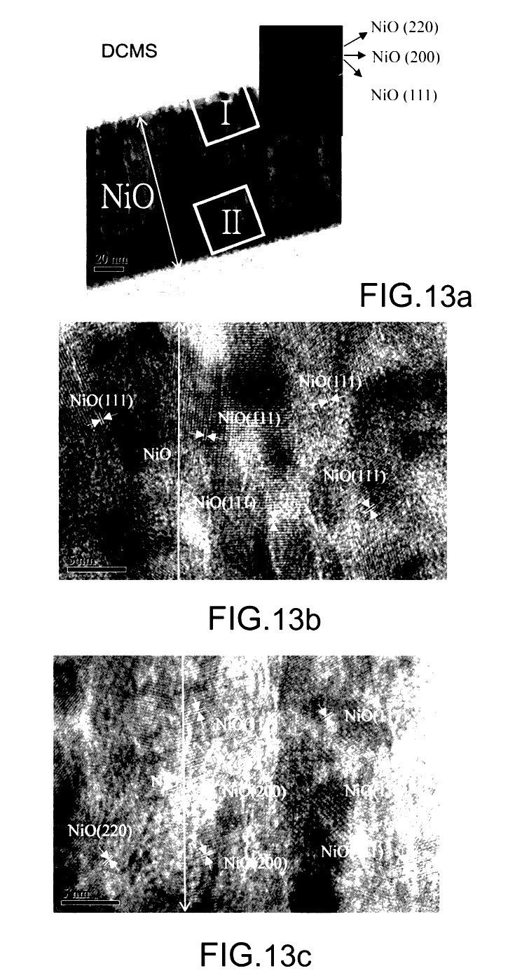

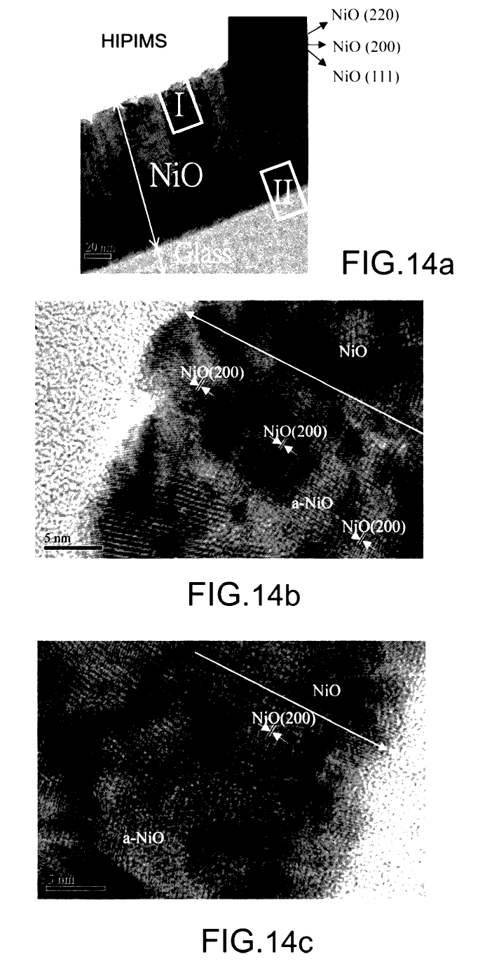

FIGS. 13a-13c show TEM cross-sectional images of DCMS (duty cycle=100%) sputtering NiO film in different amplification factors, wherein FIG. 13a has 100 K of amplification factor; FIG. 13b is crystal lattice image of region I of FIG. 13a in 800 K of amplification factor; and FIG. 13c is crystal lattice image of region II of FIG. 13a in 800 K of amplification factor. FIGS. 14a-14c show TEM cross-sectional images of HIPIMS (duty cycle=1.6%) sputtering NiO film in different amplification factors, wherein FIG. 14a has 100 K of amplification factor; FIG. 14b is crystal lattice image of region I of FIG. 14a in 800 K of amplification factor; and FIG. 14c is crystal lattice image of region II of FIG. 14a in 800 K of amplification factor. With observation of TEM cross-sectional images in low amplification factor in FIGS. 13a and 14a, internal structure is compact and the surface of the NiO film has become flat by HIPIMS with reducing the duty cycle that may facilitate to be applied to the subsequent coating operation of optoelectronic components. HIPIMS with reducing the duty cycle has higher peak pulse power density of the target, so sputtering atoms have higher energies, therefore more compact and smoother films can be formed. In addition, by means of electron diffraction pattern in a specific region and d-spacing values calculation of lattice images of high resolution, as DCMS is used to form NiO film, internal structure of the NiO film is prone to form mixed crystal faces of NiO (111) and NiO (200), and shows a random orientation, as shown in FIGS. 13b and 13c. However, in FIGS. 14b and 14c, it can be found internal structure of the NiO film is mainly formed a crystal face of NiO (200) by using HIPIMS with reducing the duty cycle to 1.6%. This describes NiO film tends to a preferred orientation of crystal face of NiO (200) by using HIPIMS with higher peak pulse power density of the target to deposit NiO film, the above results are consistent with results of XRD analysis.

6. Analysis of Optical Properties of NiO Film

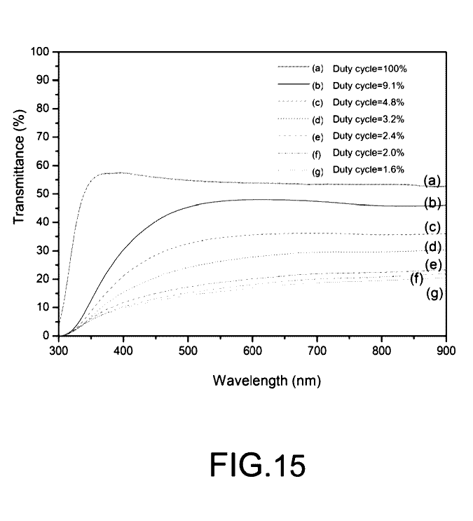

FIG. 15 shows the change of transmittance of NiO film with incident light wavelength in different duty cycles. As can be seen from FIG. 15, the transmittance of NiO film is reduced with reducing the duty cycle. The transmittance of NiO film is about 52.0% by using DCMS to deposit NiO film. The transmittance of NiO film is reduced to 47.9% by using HIPIMS with the duty cycle of 9.1% to deposit NiO film. The transmittance of NiO film is apparently reduced to 35.5% by using HIPIMS with the duty cycle of 4.8% to deposit NiO film. Further, the transmittance of NiO film is reduced to 27.7%, 20.1%, 18.1% and 16.8% as the duty cycle is reduced to 3.2%, 2.4%, 2.0% and 1.6% respectively. The more Ni vacancy sites and grain boundaries can be formed with reducing the duty cycle to deposit NiO film. The Ni vacancy sites and grain boundaries in the film increase the chance of incident light to be scattered or absorbed, the transmittance of NiO film is reduced with reducing the duty cycle.

The invention is not limited to these embodiments, but various variations and modifications may be made without departing from the scope of the invention.

What is claimed is:

1. A process for manufacturing transparent conductive oxide films, comprising operating a high power impulse magnetron sputtering system, HIPIMS system, in an argon and oxygen mixture, at peak pulse power density higher than 1000 W/cm², under a duty cycle lower than 3.2%; and sputtering a Ni target to form the p-type NiO film with high conductivity on a substrate, the duty cycle=tₒₙ/(tₒₙ+t_{off}), wherein tₒₙ is time of pulse on and t_{off} is time of pulse off.

2. The process for manufacturing transparent conductive oxide films according to claim 1, wherein the peak pulse power density is in a range between 1000 W/cm² and 2100 W/cm².

3. The process for manufacturing transparent conductive oxide films according to claim 1, wherein the working pressure is 5 m Torr.

4. The process for manufacturing transparent conductive oxide films according to claim 1, wherein the argon and oxygen mixture has argon and oxygen flow ratio of 1:1.

5. The process for manufacturing transparent conductive oxide films according to claim 1, wherein the thickness of the NiO film is 100 nm.

6. The process for manufacturing transparent conductive oxide films according to claim 1, wherein the grain size of the NiO film is in a range of 5 nm-6.5 nm.

7. The process for manufacturing transparent conductive oxide films according to claim 1, wherein the resistivity of the NiO film is in a range of 0.19 Ω-cm -0.07 Ω-cm.

8. The process for manufacturing transparent conductive oxide films according to claim 1, wherein the carrier concentration of the NiO film is in a range of 2.70×10¹⁹ cm⁻³-2.86×10²¹ cm⁻³.

9. The process for manufacturing transparent conductive oxide films according to claim 1, wherein the substrate is made by glass or silica.
